(19) United States
(12) Patent Application Publication
(10) Pub. No.: US 2018/0233410 A1
(43) Pub. Date: Aug. 16, 2018

(54) WAFER DICING METHODS

(71) Applicant: pSemi Corporation, San Diego, CA (US)

(72) Inventors: JOHN JAMES, Poway, CA (US); SERGEI VORONOV, San Diego, CA (US); NIRMAL SHARMA, Carlsbad, CA (US); KIRBY KOETZ, Carlsbad, CA (US); VINCENT DEMAIORIBUS, Carlsbad, CA (US); DOUGLAS A. HAWKS, Escondido, CA (US)

(21) Appl. No.: 15/432,838

(22) Filed: Feb. 14, 2017

(51) Int. Cl. H01L 21/78; H01L 21/683; H01L 23/544

(52) U.S. Cl. CPC H01L 21/78; H01L 2223/5446; H01L 23/544; H01L 21/6836

(57) ABSTRACT

Wafer dicing methods that simplify the singulation process for certain types of integrated circuit (IC) wafer substrates that improve device reliability and die strength, reduce the width of the cutting kerf, reduce cost, and improve yield. A first method includes making ablative scribing cuts on the front side of a wafer substrate along cutting streets around the perimeter of IC dies, followed by stealth laser dicing through the backside of the wafer substrate and in substantial alignment with the ablative scribing cuts. A second method includes making stealth laser dicing through the backside of the wafer substrate and in substantial alignment with cutting streets around the perimeter of IC dies, followed by ablative scribing cuts on the front side of a wafer substrate along the cutting streets.

### BACKGROUND

### (1) Technical Field

This invention relates to methods for the singulation of integrated circuit die from processed wafer substrates, also known as “wafer dicing”.

### (2) Background

Integrated circuits (ICs) are almost universally fabricated as multiple units formed on wafer substrates. Common wafer substrates include silicon, sapphire, silicon-on-insulator (SOI), silicon-on-sapphire (SOS), gallium arsenide, and various glasses, but a wide variety of other materials have been used. In general, multiple individual IC die, typically numbering in the hundreds to thousands, are formed as complex two-dimensional and three-dimensional patterns of insulating, semiconductive, and conductive materials on one side of a wafer substrate. IC functionality may include electronic, micromechanical, sensor, and/or other technologies.

Individual die are generally separated from other dies on a wafer substrate by cutting “streets” (also known as dicing “lanes” or kerfs). Die singulation, also known as wafer dicing, is part of the die preparation flow in the fabrication process that separates individual die on a finished wafer substrate for further packaging or direct usage. Wafer dicing is one of the most critical elements of the IC fabrication process, where reduction of defects and improvements in quality can make a significant contribution to final yield and per unit costs for the ICs. Defects may include chipped IC die edges and stress fractures that reduce IC die strength and increase the chance of breaking during later assembly steps or in actual use.

A number of mechanical-based and non-mechanical methods have been developed for singulating dies from a wafer substrate along cutting streets. Mechanical-based methods include, for example, diamond scribing to create cleave lines (followed by breaking, such as by bending the wafer substrate), and rotary blade saws to create partial-depth cleave lines or full-depth cuts through a wafer substrate. Non-mechanical methods include, for example, ablative lasers that essentially sublime and/or vaporize material, plasma etching that uses hot ions to essentially vaporize and “sand blast” material, and so-called stealth dicing based on use of infrared (IR) lasers to create subsurface sites suitable to form preferred cleaving planes. For purposes of this document, these and other singulation methods will be considered to generate a cut along cutting streets of a wafer substrate.

With respect to stealth dicing, a number of thin wafer substrate materials, such as silicon, are substantially transparent to infrared light. Stealth dicing IR lasers penetrate the backside surface of such wafer substrates and focused heating from the laser creates highly localized and brief melting, transforming crystalline material (e.g., silicon) into a modified material (e.g., polycrystalline silicon) surrounded by a field of concentrated stress and micro cracks. The IR laser is sequentially focused at different depths in a wafer substrate, so that stacked vertical planes of modified material are formed. These subsurface modified layers essentially create weakened cleaving planes that enable mechanical separation. Stealth dicing generally leaves no visible marks on the wafer's outer surface.

The chosen method of wafer dicing generally depends on such factors as wafer substrate material and thickness, presence of complicating materials (e.g., metal, test element groups (TEGs), etc.) within the cutting streets (“in-street structures”), metallization on the backside of a wafer substrate, defect type and degree, and kerf width produced by the singulating method (wide kerfs reduce the number of available dies from a wafer substrate). For example, the presence of metal and/or TEGs within cutting streets generally prohibits use of cutting saws, since such in-street structures may clog a saw. Rotary blade cutting and mechanical scribing can also cause die edge chipping or cracking, leading to lower yields, and both methods generally have relatively wide kerfs (e.g., greater than about 50 μm). Backside metallization may prohibit use of certain laser-based methods, or pose cutter alignment problems. Stealth dicing does not work for IC dies having in-street metal or TEGs on the patterned front side of a wafer substrate, since the subsurface modified layers do not cut the front-side structures, resulting in errant breaks in the metal and/or inability to separate dies.

Another problem of wafer dicing is developing efficient cutting plans for all wafer substrates. Most production wafer substrates are dedicated to same-size rectangular IC dies arrayed in a two-dimensional rectangular grid. Accordingly, most or all of such IC dies can be placed on a chuck and separated by making a first set of parallel straight-line cuts across a wafer substrate, followed by a second set of orthogonal parallel straight-line cuts across the wafer substrate (the cutter is generally affixed to a processing head that can be programmed with X-Y translation movements). However, some wafer substrates, referred to as multi-project wafers or multi-product wafers (MPWs), contain different size IC dies and/or non-uniform grid pattern layouts of ICs and/or non-rectangular ICs.

For example, FIG. 1A is diagram of an exemplary prior art exposure field, or pattern, 100 containing multiple instances of three different IC die types 102 (Die 1, Die 2, Die 3) in an MPW configuration. The exposure field of FIG. 1A is often stepped and repeated across a wafer substrate (which is generally circular) resulting in an array of patterns such as shown in FIG. 1A. FIG. 1B is a diagram showing the wafer pattern 100 of FIG. 1A and a first set of cutting paths 104 for separating two of the instances of IC die type Die 1. Using conventional straight-line cuts across the pattern 100, a cutting plan that separates out the top two instances of target Die 1 will cut through, and therefore destroy, all instances of Die 2 and Die 3, and the remaining three instances of Die 1. Similarly, FIG. 1C is a diagram showing the pattern 100 of FIG. 1A and a second set of cutting paths 104 for separating the instances of IC die type Die 3. Using conventional straight-line cuts across the pattern 100, the cutting plan shown will separate out the three instances of target Die 3, but destroy all instances of Die 1 and Die 2. Similarly, a cutting plan for separating the instances of target Die 2 would destroy most instances of Die 1 and Die 3, while a set of cutting paths for separating the bottom instances of target Die 1 would destroy all instances of Die 2 and Die 3. In general, to separate out all ten illustrated IC dies from the pattern 100 when applied to a wafer substrate would require cutting four separate but identically patterned wafer substrates, four cutting plans, and four process cycles. For more complex MPW patterns, the number of wafers and cutting plans may be 12 or more, thereby driving up cost and complexity. As should be clear, such a process is wasteful of wafer substrates and time consuming, particularly if the number of IC die types increases and the total number of dies increases.

To deal with non-uniform grid layouts of ICs such as those shown in FIG. 1A, a wafer cutting method known as a “hasen” (Japanese for “dashed line”) cut has been developed using an ablative laser that can be intermittently stopped and started. Most ablative lasers are pulsed, but at fairly high rates so as to create essentially continuous cuts. However, hasen cut lasers can be stopped from cutting so that the processing head can be repositioned to a new location and cutting recommenced, and accordingly have the ability to stop or start at junctions. For example, FIG. 1D is a diagram showing a highly-magnified wafer substrate 110 surface hasen-cut by a laser beam 120 focused by a lens 122 (the boundaries of adjacent IC dies are omitted for clarity). By controlling the ON-OFF state of the laser beam 120, a set of three in-line scribe cuts 124a-124c, spaced apart, have already been made by the focused laser beam 120. In a subsequent pass of the processing head, a new cut 126 is being made perpendicular to and starting from the middle of the second scribe cut 124b.

Despite the various cutting methods that have been developed for various combinations of IC dies and wafer substrate characteristics, there is still a need for improved wafer dicing methods for certain types of wafer substrates that simplify the singulation process, improve device reliability and die strength, reduce cutting kerf and hence reduce cutting street width, and improve yield. The present invention addresses this need.

### SUMMARY OF THE INVENTION

The present invention encompasses improved wafer dicing methods that simplify the singulation process for certain types of wafer substrates, improve device reliability and die strength, reduce the width of the cutting kerf, reduce cost and improve yield. Embodiments of the invention can effectively recover essentially all integrated circuit (IC) dies of different sizes on a wafer substrate without sacrificing any IC die of interest and can be used as well with wafer substrates having uniformly sized IC dies. The fine cuts available with the inventive methods allow extending dicing of ICs to as small as 0.4 mm of a die side size and allow singulation kerf widths to be essentially only limited by the focus spot diameter of an ablative laser.

A first method of dicing a wafer substrate (which may be an MPW) patterned on its front side with integrated circuit (IC) dies and having its backside adhered to a dicing tape (DT) includes the steps of:
mapping target IC dies on the patterned front-side of the wafer substrate to determine the location of cutting streets;
from the front side of the wafer substrate, using an ablative laser to make wafer substrate pre-scoring scribing passes around target IC dies inside the mapped cutting streets sufficient to clear surface material from a region of the cutting streets (for wafer substrates having IC dies patterned in a non-uniform grid pattern, such as MPWs, the scribing passes are made using hasen cuts);
mapping target IC dies on the patterned front-side of the wafer substrate to determine the location of the front-side ablative laser scribed cuts;
from the backside of the wafer substrate, using a penetrating laser focused inside the wafer substrate to make stealth dicing passes around target IC dies substantially aligned with the mapped front-side ablative laser pre-scoring scribed cuts (for wafer substrates having IC dies patterned in a non-uniform grid pattern, the stealth dicing passes are made using hasen cuts); and
expanding the wafer substrate by stretching the dicing tape so as to stress all laser processed IC dies, thereby separating the IC dies from the wafer substrate along lines defined by the pre-scoring scribed cuts and the stealth dicing passes.

A second method of dicing a wafer substrate (which may be an MPW) patterned on its front side with IC dies and having its backside adhered to a DT includes the steps of:
mapping target IC dies on the patterned front-side of the wafer substrate to determine the location of cutting streets;
from the backside of the wafer substrate, using a penetrating laser focused inside the wafer substrate to make stealth dicing passes around target IC dies substantially aligned with the mapped cutting streets (for wafer substrates having IC dies patterned in a non-uniform grid pattern, the stealth dicing passes are made using hasen cuts);
optionally, re-mapping target IC dies on the patterned front-side of the wafer substrate to determine the location of the front-side ablative laser scribed cuts;
from the front side of the wafer substrate, using an ablative laser to make wafer substrate pre-scoring scribing passes around target IC dies inside the mapped cutting streets sufficient to clear surface material from a region of the cutting streets (for wafer substrates having IC dies patterned in a non-uniform grid pattern, such as MPWs, the scribing passes are made using hasen cuts); and
expanding the wafer substrate by stretching the dicing tape so as to stress all laser processed IC dies, thereby separating the IC dies from the wafer substrate along lines defined by the stealth dicing passes and the pre-scoring scribed cuts.

Variants of the above method include pre-singulation preparatory steps for the wafer substrate such as wafer thinning and dicing tape adherence, and post-singulation steps such as dicing tape adhesion release (e.g., with UV light) and die picking.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1A is diagram of an exemplary prior art exposure field, or pattern, containing multiple instances of three different IC die types (Die 1, Die 2, Die 3) in an MPW configuration.

FIG. 1B is a diagram showing the pattern of FIG. 1A and a first set of cutting paths for separating two of the instances of IC die type Die 1.

FIG. 1C is a diagram showing the pattern of FIG. 1A and a second set of cutting paths for separating the instances of IC die type Die 3.

FIG. 1D is a diagram showing a highly-magnified wafer substrate surface hasen-cut by a laser beam focused by a lens.

FIG. 2A is a process diagram showing a first method, in accordance with the invention, of dicing a wafer substrate (which may be an MPW) patterned on its front side with IC dies and having its backside adhered to a dicing tape.

FIG. 2B is a process diagram showing a second method, in accordance with the invention, of dicing a wafer substrate (which may be an MPW) patterned on its front side with IC dies and having its backside adhered to a dicing tape.

FIG. 3A is a top plan view of a wafer substrate patterned by an exposure field containing multiple instances of three different IC die types (Die 1, Die 2, Die 3) in an MPW configuration.

FIG. 3B is a cross-sectional view of the patterned wafer substrate of FIG. 3A showing a cutting street between regions of patterned structures of two adjacent IC dies.

FIG. 3C is an enlarged view of the cross-section of the patterned wafer substrate of FIG. 3B.

FIG. 4A is a top plan view of the patterned wafer substrate of FIG. 3A containing multiple instances of three different IC die types (Die 1, Die 2, Die 3).

FIG. 4B is a cross-sectional view of the patterned wafer substrate of FIG. 4A, showing a scribed cut made by an ablative laser beam focused by a lens.

FIG. 5A is a bottom plan view of the patterned wafer substrate of FIG. 4A showing the mirror-image outline of three different IC die types (Die 1, Die 2, Die 3) formed on the front side of the wafer substrate.

FIG. 5B is a cross-sectional view of the patterned wafer substrate of FIG. 5A.

FIG. 6A is a top plan view showing a patterned wafer substrate mounted on a plane of DT before expansion.

FIG. 6B is a top plan view showing IC dies singulated from a patterned wafer substrate and still mounted on a plane of DT after expansion.

FIG. 7 is a pictorial diagram summarizing one embodiment of the inventive wafer dicing method, and including several pre-singulation preparatory steps for a patterned wafer substrate and a post-singulation step.

Like reference numbers and designations in the various drawings indicate like elements.

### DETAILED DESCRIPTION OF THE INVENTION

The present invention encompasses improved wafer dicing methods that simplify the singulation process for certain types of wafer substrates, improve device reliability and die strength, reduce the width of the cutting kerf, reduce cost and improve yield. Embodiments of the invention can effectively recover essentially all integrated circuit (IC) dies of different sizes on a wafer substrate without sacrificing any IC die of interest. and can be used as well with wafer substrates having uniformly sized IC. The fine cuts available with the inventive methods allow extending dicing of ICs to as small as 0.4 mm of a die side size and allow singulation kerf widths to be essentially only limited by the focus spot diameter of an ablative laser.

Overview

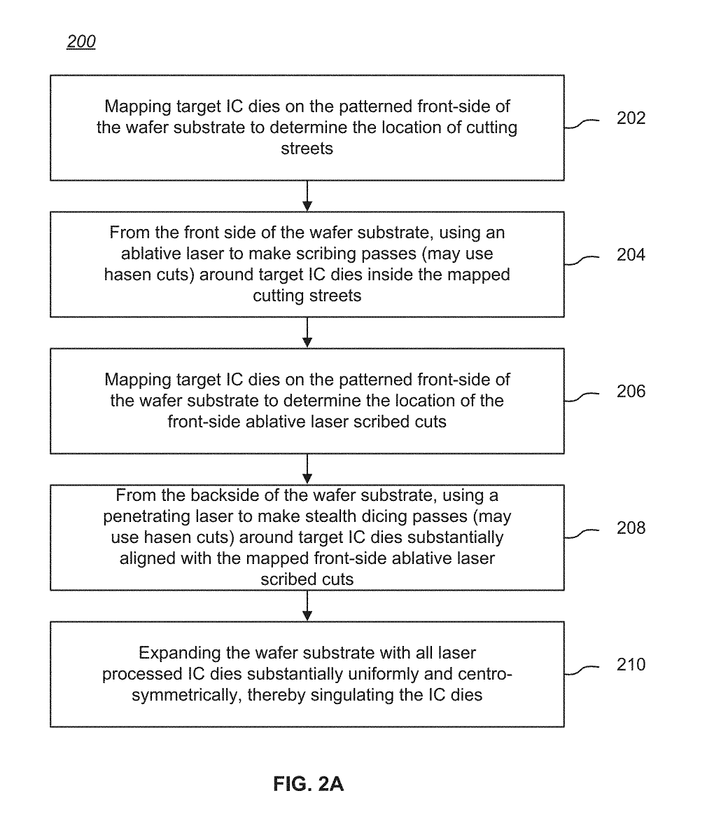

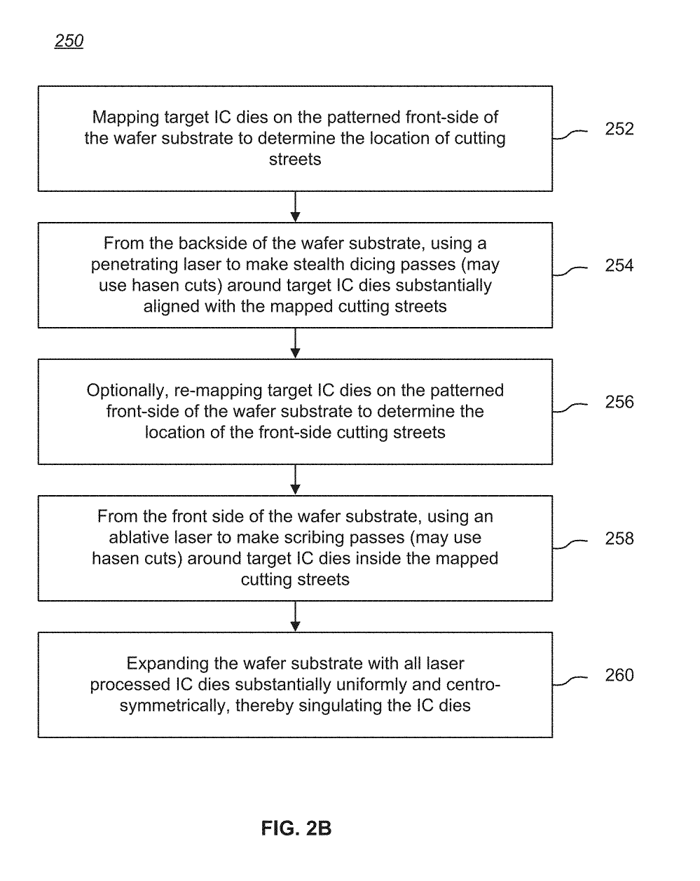

FIG. 2A is a process diagram 200 showing a first method, in accordance with the invention, of dicing a wafer substrate (which may be an MPW) patterned on its front side with IC dies and having its backside adhered to a dicing tape. As is known, dicing tape (DT) is a backing tape used to hold IC dies together during the wafer dicing process, mounting the IC dies to a frame. The IC dies are later removed from the DT further on in the manufacturing process.

The example process for “ablative scribing before stealth dicing” includes the steps of:
Mapping target IC dies on the patterned front-side of the wafer substrate to determine the location of cutting streets (STEP 202).
From the front side of the wafer substrate, using an ablative laser to make wafer substrate pre-scoring scribing passes around target IC dies inside the mapped cutting streets sufficient to clear surface material from a region of the cutting streets (for wafer substrates having IC dies patterned in a non-uniform grid pattern, such as MPWs, the scribing passes are made using hasen cuts) (STEP 204).
Mapping target IC dies on the patterned front-side of the wafer substrate to determine the location of the front-side ablative laser scribed cuts (STEP 206). This step may be optional, depending on the accuracy of the ablative front side cutting relative to a pre-determined cutting plan that may be used in the stealth dicing step.
From the backside of the wafer substrate, using a penetrating laser focused inside the wafer substrate to make stealth dicing passes around target IC dies substantially aligned with the mapped front-side ablative laser pre-scoring scribed cuts (for wafer substrates having IC dies patterned in a non-uniform grid pattern, the stealth dicing passes are made using hasen cuts) (STEP 208).
Expanding the wafer substrate by stretching the dicing tape so as to stress all laser processed IC dies (e.g., centro-symmetric expansion), thereby separating the IC dies from the wafer substrate along lines defined by the pre-scoring scribed cuts and the stealth dicing passes (STEP 210).

FIG. 2B is a process diagram 250 showing a second method, in accordance with the invention, of dicing a wafer substrate (which may be an MPW) patterned on its front side with IC dies and having its backside adhered to a dicing tape. The example process “stealth dicing before ablative scribing” includes the steps of:
Mapping target IC dies on the patterned front-side of the wafer substrate to determine the location of cutting streets (STEP 252).
From the backside of the wafer substrate, using a penetrating laser focused inside the wafer substrate to make stealth dicing passes around target IC dies substantially aligned with the mapped cutting streets (for wafer substrates having IC dies patterned in a non-uniform grid pattern, the stealth dicing passes are made using hasen cuts) (STEP 254).
Optionally, re-mapping target IC dies on the patterned front-side of the wafer substrate to determine the location of the front side cutting streets (STEP 256). The need to perform this step may depend on the accuracy of a pre-determined cutting plan used in the stealth dicing step.
From the front side of the wafer substrate, using an ablative laser to make wafer substrate pre-scoring scribing passes around target IC dies inside the mapped cutting streets sufficient to clear surface material from a region of the cutting streets (for wafer substrates having IC dies patterned in a non-uniform grid pattern, such as MPWs, the scribing passes are made using hasen cuts) (STEP 258).
Expanding the wafer substrate by stretching the dicing tape so as to stress all laser processed IC dies (e.g., centro-symmetric expansion), thereby separating the IC dies from the wafer substrate along lines defined by the stealth dicing passes and the pre-scoring scribed cuts (STEP 260).

Variants of the above method include pre-singulation preparatory steps for the wafer substrate such as wafer thinning and dicing tape adherence, and post-singulation steps such as dicing tape adhesion release (e.g., with UV light) and die picking.

### Ablative Scribing Before Stealth Dicing Example

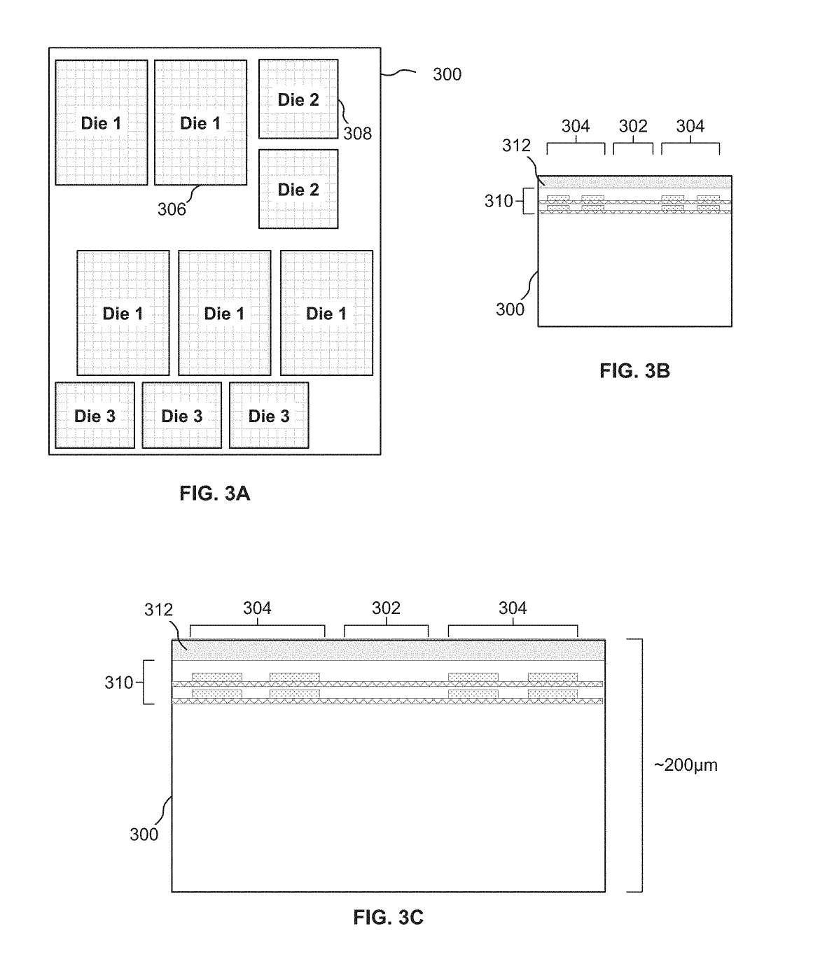

FIG. 3A is a top plan view of a wafer substrate 300 patterned by an exposure field containing multiple instances of three different IC die types (Die 1, Die 2, Die 3) in an MPW configuration (note again that wafer substrates are generally circular; a rectangular wafer substrate 300 is shown for compactness of illustration). The wafer substrate 300 may be formed of a number of different materials that are compatible with the methods of the invention, including (but not limited to) silicon, sapphire, SOL SOS, piezoelectric substrates (e.g., quartz, LiNbO₂, LiTaO₃), and at least some glasses and ceramics.

FIG. 3B is a cross-sectional view of the patterned wafer substrate 300 of FIG. 3A showing a cutting street 302 between regions of patterned structures 304 of two adjacent IC dies (e.g., Die 1 306 and Die 2 308). In general, as is known, a buffer zone or “set back” is defined around each IC die such that a cutting street 302 is spaced from the perimeter of the IC die, to prevent damage to the IC die when a cut is made along the cutting street 302.

FIG. 3C is an enlarged view of the cross-section of the patterned wafer substrate 300 of FIG. 3B. A wafer substrate 300 may be relatively thick (e.g., approximately 400-1,000 μm during fab) during patterning of the IC dies on the front-side, but with current technology, the wafer substrate 300 is generally thinned to about 50-300 μm after patterning and before singulation. Other thicknesses may be used for particular applications, so long as compatible with the laser scribing and stealth dicing processes set forth in this disclosure. Thinning creates a thinner final die thickness and thus allows for low profile electronic assemblies. Substrate thinning may also improve singulation yield and certain operational characteristics of the IC dies. Substrate thinning may be accomplished by a number of known techniques, such as backside grinding. In the illustrated example, the wafer substrate 300 is about 200 μm thick, but the methods of the present invention are not limited to that particular thickness.

One or more layers 310 of various structures may be formed in known fashion within and/or on the front side of the bulk of the wafer substrate 300. The structures are generally two-dimensional and three-dimensional patterns of insulating, semiconductive, and conductive materials and may include electronic, micromechanical, sensor, and/or other technologies. The thickness of each of the formed layers 310 is generally relatively small (e.g., often less than about 1 um) compared to the thickness of the thinned wafer substrate 300 as a whole; the illustration exaggerates the vertical dimension of the formed layers 310 for purposes of clarity. In general, before singulation cutting commences, a protective coating or film 312 may be applied in known fashion to the front side of the wafer substrate 300 to prevent damage to the IC dies from the singulation process. For example, a compound including polyvinyl alcohol (PVA) may be applied to the front side of the wafer substrate 300 before laser ablation to protect the front surface from debris caused by the laser ablation process. After laser ablation, the PVA may be washed from the wafer surface.

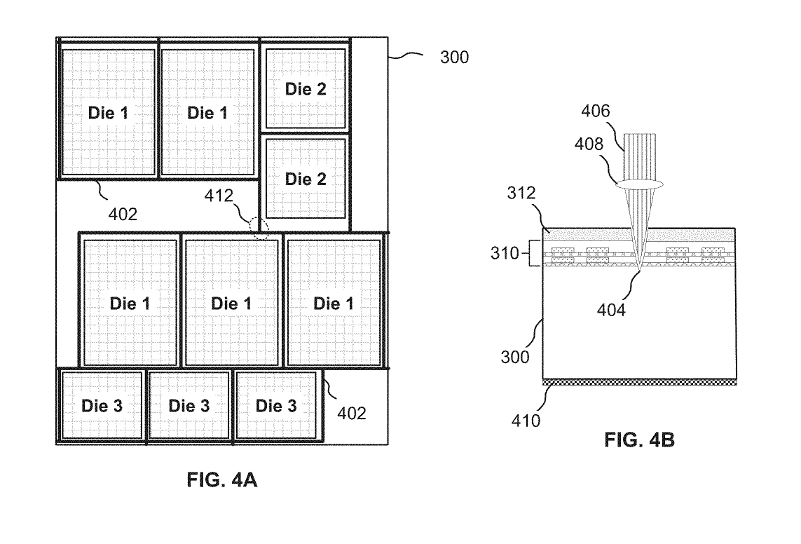

FIG. 4A is a top plan view of the patterned wafer substrate 300 of FIG. 3A containing multiple instances of three different IC die types (Die 1, Die 2, Die 3). The patterned front side of the wafer substrate 300 is mapped directly or indirectly to determine the location of cutting streets relative to the IC dies. For example, a Graphic Database System stream format (common acronym GDSII) is a database file format which is the de facto industry standard for data exchange of IC layout artwork. A GDSII binary file format represents planar geometric shapes, text labels, and other information about an IC layout. The data can be used to reconstruct all or part of the artwork to be used in sharing IC layouts, transferring artwork between different tools, or creating photomasks for fabrication of an IC. Consequently, such a data file representing a particular exposure field or pattern may be downloaded to a laser groove and/or stealth dicing system to create a cutting plan for the patterned wafer substrate 300, in known fashion. As another example, a microscope imaging system may be used to optically scan the front side of the patterned wafer substrate 300 and create a cutting plan. The scan may be, for example, an X-scan/Y-scan or a raster scan. In either case, the heavy lines 402 in FIG. 4A depict a cutting plan for the illustrated layout of IC dies on the patterned wafer substrate 300.

Once the cutting plan is determined, an ablative laser is automatically guided by the cutting plan to make pre-scoring scribing passes around the target IC dies inside the mapped cutting streets, and thus all around the target IC dies. Ablation is a method that sublimes and/or vaporizes a solid workpiece by irradiating it with a focused laser beam (typically a UV laser having a wavelength of about 355 nm) for a short period of time (e.g., a laser pulse duration on the order of femto-seconds through nano-seconds, at a repetition rate of kilohertz through megahertz); multiple adjacent pulses provide for essentially continuous cutting. An ablative laser generally provides high-speed and high-quality cutting, and may be co-mounted with a mapping imaging system on the same processing head. In addition, by focusing the laser beam on a spot less than about 20 μm, and especially less than about 10 μm in diameter, a significant street-width reduction can be achieved in comparison to some other dicing processes, thus generally enabling an increase in the number of IC dies per wafer substrate by crowding the IC dies closer together. For comparison, the kerf of a wafer cutting saw is typically at least about 50 μm.

FIG. 4B is a cross-sectional view of the patterned wafer substrate 300 of FIG. 4A, showing a scribed cut 404 made by an ablative laser beam 406 focused by a lens 408. In this example, a dicing tape (DT) 410 has been adhered to the backside of the wafer substrate 300 in known fashion, either alone, or as part of a “die attach film on dicing tape” combination, available commercially. It is important that the DT 410 be compatible with a stealth dicing laser process (i.e., essentially transparent to infrared wavelengths). It is useful that the DT 410 be compatible with the expansion process (e.g., have sufficient adhesion and stretchability that attached IC die separate from each other but do not detach from the tape during expansion of the DT 410).

An important aspect of the process is that the pre-scoring scribing passes should be sufficient to clear surface material from a region of the cutting streets (e.g., cutting through metal features in the cutting streets) and help create stress lines within the front surface of the patterned wafer substrate 300. Thus, in general, one or more passes of the focused ablative laser beam 406 are made along the cutting plan lines 402 shown in FIG. 4A until the scribed cut 404 is deep enough to cut through and/or remove all material from the lased section of the in-street structures (e.g., metallization, TEGs, etc.). In some cases, it may be useful to make one or more passes with a narrowly focused ablative laser beam 406 to make deep, narrow cuts, followed by one or more passes with a slightly defocused ablative laser beam 406 to make shallower broad cuts to ensure that in-street structures in cutting streets are fully cut and/or removed.

It has been found that deeper ablative cutting, into the original bulk material of the wafer substrate 300 (i.e., below the formed layers 310), generally has the beneficial effect of creating the beginnings of a cleavage plane in the wafer substrate 300 that, in combination with subsequent stealth dicing, further enhances die singulation. The cutting depth may vary with the type of wafer substrate material.

For wafer substrates 300 having IC dies patterned in a non-rectangular grid, such as the MPW of FIG. 4A, the ablative laser scribing passes are made using hasen cuts. For example, the cutting plan shown in FIG. 4A shows a number of intersections in which the laser beam is set to an OFF state; one such intersection is shown surrounded by a dotted oval 412, where a vertical cut intersects a horizontal cut. As should be clear, by making hasen cuts, the cutting streets surrounding each of the ten illustrated IC dies can be individually scribed without cutting through and thus sacrificing other IC dies.

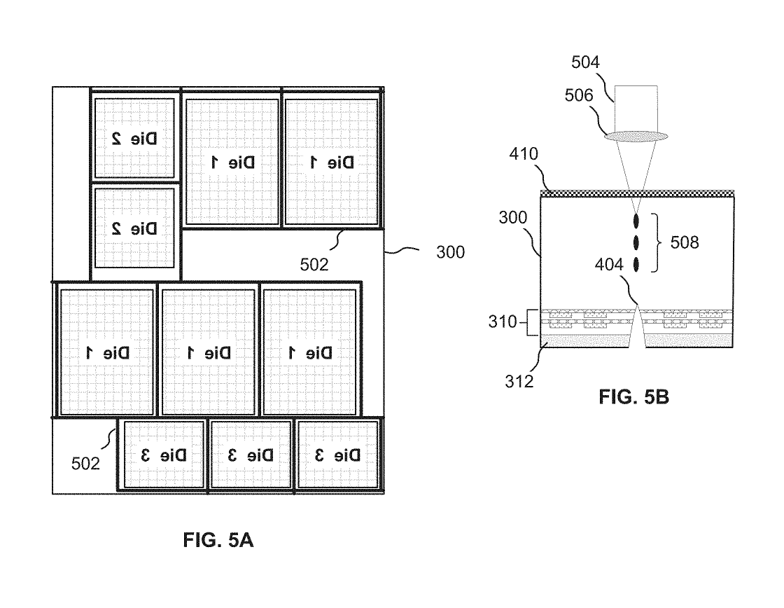

FIG. 5A is a bottom plan view of the patterned wafer substrate 300 of FIG. 4A showing the mirror-image outline of three different IC die types (Die 1, Die 2, Die 3) formed on the front side of the wafer substrate 300. In essence, FIG. 5A is a “flipped” version of FIG. 4A, viewing the wafer substrate 300 from its backside. Note that at visible wavelengths, the outlines of the IC dies may not be discernable to the human eye from the backside, depending on the material of the wafer substrate 300.

All IC dies on the patterned front-side of the wafer substrate are mapped to determine the location of the front-side IC dies and ablative laser scribed cuts 404. For certain substrate types, such as silicon and sapphire, the IC dies formed on the front side of the wafer substrate 300 and the front-side ablative laser scribed cuts 404 are visible to an IR microscope imaging system from the backside of the wafer substrate 300 (for sapphire, the front-side ablative laser scribed cuts 404 may be visible at visible wavelengths as well). Accordingly, an IR imaging system may be used to scan the backside of the wafer substrate 300 and create a stealth dicing laser cutting plan, in known fashion. Alternatively, mapping may be performed by a microscope imaging system (visible light or IR) from the front side of the wafer substrate 300, and the coordinates transformed appropriately to a representation of the IC die and ablative laser scribed cut positions as they would be “seen” from the backside of the wafer substrate 300. Thus, such an imaging system may be used to scan the front side of the wafer substrate 300 and create a stealth dicing laser cutting plan, in known fashion. The heavy lines 502 in FIG. 5A depict a mapped stealth dicing laser cutting plan for the example layout of IC dies.

FIG. 5B is a cross-sectional view of the patterned wafer substrate 300 of FIG. 5A. The wafer substrate 300 is now positioned such that its backside faces an IR stealth dicing laser beam 504 focused by a lens 506. The IR stealth dicing laser beam 504 can penetrate wafer substrates made of materials (e.g., silicon or sapphire) that are substantially transparent to infrared light, and create subsurface modified layers 508 which essentially create weakened planes that enable mechanical separation (e.g., by expanding, pulling, or bending). The IR stealth dicing laser beam 504 will also penetrate the adhered DT 410, since the DT 410 is specifically chosen to be essentially transparent to IR wavelengths.

Multiple passes of the IR stealth dicing laser beam 504 with different focal points may be made to create multiple subsurface modified layers 508 at different depths underneath the backside of the wafer substrate 300. Three such modified layers 508 are shown in the illustrated example, but more or fewer layers may be used, generally as a function of the thickness of the wafer substrate 300. (Note that the three black ovals representing the modified layers 508 are seen end-on in FIG. 5B; an orthogonal view would show three essentially continuous lines between ON and OFF states of the IR stealth dicing laser beam 504).

Because the cutting plan for the IR stealth dicing laser beam 504 is based on the mapped positions of the front-side IC dies and ablative laser scribed cuts 404, the subsurface modified layers 508 created by stealth dicing passes around the target IC dies will be substantially aligned with the mapped front-side ablative laser scribed cuts 404. Such alignment enhances cleaving along planes defined by the front-side ablative laser scribed cuts 404 and the aligned modified layers 508 created through the backside of the wafer substrate 300 by the IR stealth dicing laser beam 504. For wafer substrates 300 having IC dies patterned in a non-uniform grid pattern, such as the MPW of FIG. 5A, the stealth dicing passes are made using hasen cuts. As should be clear, by making hasen cuts, the stealth dicing “cuts” around each of the ten illustrated IC dies can be made without making stealth dicing cuts beneath—and thus sacrificing—other IC dies.

Of note, stealth dicing essentially has no kerf width and thus greatly contributes to street-width reduction, generally enabling an increase in the number of IC dies per wafer substrate by crowding the IC dies closer together.

The IC dies may be singulated from the wafer substrate 300 along the cleaving planes defined by the front-side ablative laser scribed cuts 404 and the aligned modified layers 508 created through the backside of the wafer substrate 300 by the IR stealth dicing laser beam 504. According to one method, the DT 410 on which the wafer substrate 300 is mounted is expanded in known fashion (e.g., centro-symmetric expansion), thereby mechanically stressing the cleaving planes until they break, thus singulating the IC dies.

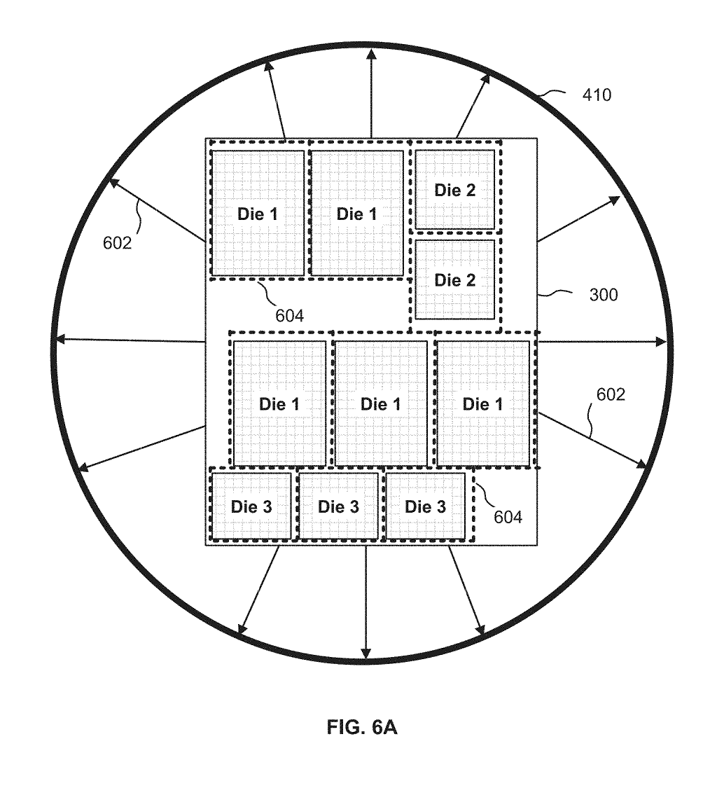

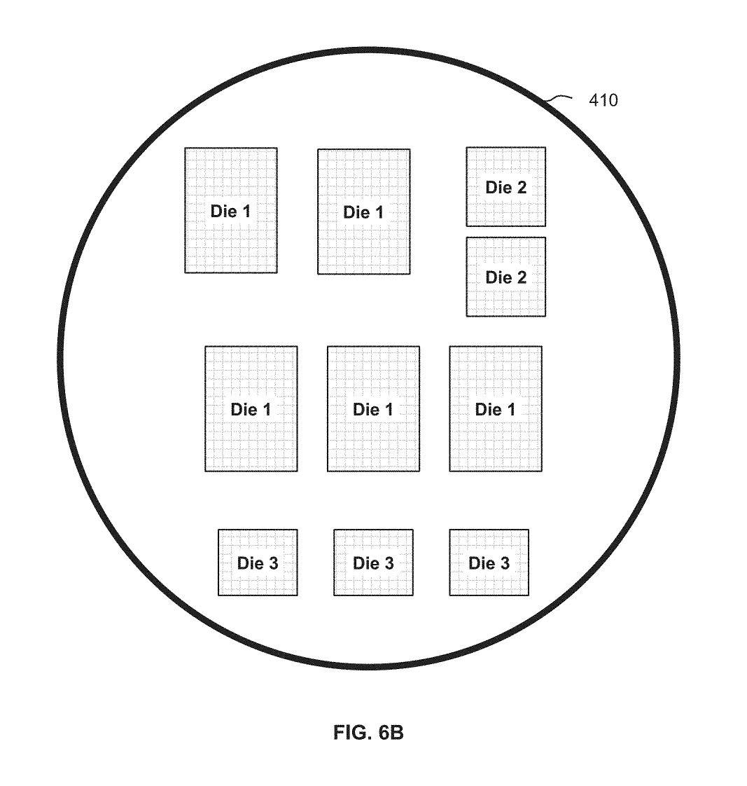

For example, FIG. 6A is a top plan view showing a patterned wafer substrate 300 mounted on a membrane of DT 410 before expansion. The mounted wafer substrate 300 may be placed in a commercial wafer handling system that expands the DT 410 centro-symmetrically, as indicated by the radial arrows 602. The mechanically stress from such expansion will pull the IC dies apart at the cleaving planes (indicated by dotted lines 604). FIG. 6B is a top plan view showing IC dies singulated from a patterned wafer substrate 300 but still mounted on a membrane of DT 410 after expansion.

Centro-symmetric expansion is particularly advantageous for MPWs, since the cleaving planes will not form sets of parallel and regular X-Y lines. However, other known mechanical methods of breaking the wafer substrate 300 along the cleaving planes may be used for wafer substrates having IC dies patterned in a rectangular grid. After singulation, the IC dies may be picked and placed in conventional fashion (e.g., to a tape-and-reel machine).

### Stealth Dicing Before Ablative Scribing Example

In an alternative embodiment, the process illustrated in FIGS. 4A-4B and 5A-5B may be carried out in essentially reverse order, where stealth dicing is performed before ablative scribing. The basic difference is that creating a cutting plan for the stealth dicing laser is based on mapping only IC dies and cutting streets on the front side of an IC die, since laser scribed cuts would not yet have been made. The steps would be as set forth in FIG. 2B and described above.

With the “stealth dicing before ablative scribing” method, mapping of target IC dies on the patterned front-side of the wafer substrate to determine the location of cutting streets before stealth dicing may be performed from the backside or front side of the wafer substrate. The mapping step need only be carried out once, in theory, if the stealth laser and the ablative laser are aligned or can be aligned to the same mapping system. Thus, as mentioned above, use of a single mapping is possible for both sequence orders of the two laser passes (i.e., ablative scribing, then stealth dicing, or stealth dicing, then ablative scribing), depending on accuracy of alignment of the laser cutting tool to the mapping tool. Optionally, the target IC dies on the patterned front-side of the wafer substrate can be separately re-mapped to determine the location of the front-side ablative laser scribed cuts.

### Experimental Results

In one experiment, multiple rectangular IC dies of various sizes were formed in an MPW configuration on a 200 μm thick wafer substrate, with cutting streets having metal of about 10-12 μm thickness. Three ablative laser scribing passes were made within the cutting streets using hasen cuts. The ablative cutting laser was focused to a spot diameter of about 13.25 μm, and made a scribed cut through the metal in the cutting streets and extending about 32.15 μm below the surface of the wafer substrate. After hasen cut stealth dicing, the IC dies, mounted on a dicing tape (DT), were separated by centro-symmetric expansion of the DT with no cracks or chipouts on their edges. Nearly 100% of the IC dies were recovered, even at IC die sizes as small as 0.4 mm square. This outcome was an unexpected result for at least two reasons. First, using stealth dicing alone, IC die sizes have been limited to no less than about 1.0 mm square, and there was no expectation that making scribing cuts on the front side of a wafer substrate would change that parameter. Second, the amount of force transferred from the expanding DT to the cleaving planes of each IC die is a function of die size, and thus it was expected that smaller IC dies would not break and separate as readily as large IC dies. However, using the current invention, the cleaving planes formed by the combination of front-side ablative laser scribed cuts 404 (particularly cuts extending into the bulk material of a wafer substrate 300 below the formed layers 310) and the aligned modified layers 508 created through the backside of the wafer substrate 300 by stealth dicing reduce the force needed to singulate the IC dies.

While the above examples have illustrated singulation of essentially all dies from a wafer substrate, in some cases, the same process may be used to singulate only selected target dies. For examples, referring to FIG. 3A, cutting plans could be developed that singulate only the Die 1 IC die type. However, even in that case, the inventive method allows singulation of all five instances of Die 1 from a single wafer substrate, compared to the two wafers required when using straight line cutting methods.

### Summary Example

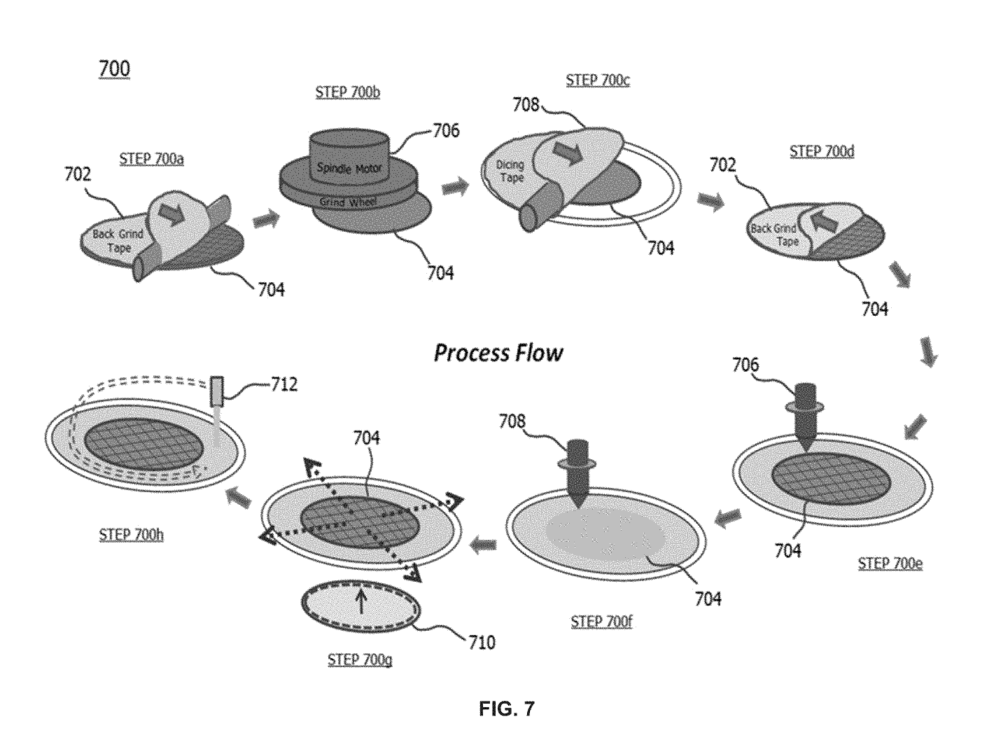

FIG. 7 is a pictorial diagram 700 summarizing one embodiment of the inventive wafer dicing method, and including several pre-singulation preparatory steps for a patterned wafer substrate and a post-singulation step. Note that other steps may be performed as desired before, after, or in-between the illustrated steps, as necessary or desirable for a particular type of wafer substrate or processing technology.

In STEP 700a, a grinding tape 702 is adhered to the front side of a wafer substrate 704 which has been patterned on its front side with IC dies.

In STEP 700b, the backside of the wafer substrate 704 is ground down by a grinder 706 to achieve a desired thickness for the wafer substrate 704. Optionally, the backside of the wafer substrate 704 may be polished after grinding (not shown).

In STEP 700c, a dicing tape (DT) 708 transparent to infrared wavelengths is adhered to the backside of the thinned wafer substrate 704.

In STEP 700d, the grinding tape 702 is removed from the front side of the wafer substrate 704. Optionally, a protective coating may be applied to the front side of the wafer substrate 704.

In STEP 700e, the front side of the wafer substrate 704 is mapped to create a first cutting plan, as described above, and an ablative laser 706 makes scribed cuts on the front side of the wafer substrate 704 as determined by the first cutting plan. Hasen ablative cuts are used for MPWs.

In STEP 700f, the front side of the wafer substrate 704 is again mapped (from the backside, using an IR imaging system, or directly from the front side) to create a second cutting plan, as described above, and an IR laser 708 makes stealth dicing “cuts” (i.e., subsurface modified layers) as determined by the second cutting plan but from the backside of the wafer substrate 704. Hasen stealth dicing cuts are used for MPWs.

In STEP 700g, the wafer substrate 704 is expanded centro-symmetrically to break apart the IC dies along cleaving planes formed by the front-side ablative laser scribed cuts and the aligned modified layers created through the backside of the wafer substrate 704 by the IR laser 708. Expansion may be performed, for example, by an expansion chuck 710 pushing up on the bottom side of the DT to stretch the tape, in known fashion.

In STEP 700h, infrared energy from an emitter 712 (e.g., a far infrared, or FIR, emitter) may be used to “heat shrink” some or all of the DT, stabilizing the tape so as to hold the amount of expansion initiated during STEP 700g.

Other conventional post-singulation steps may be applied as well, such as dicing tape adhesion release (e.g., with UV light) and die picking.

### Benefits of the Invention

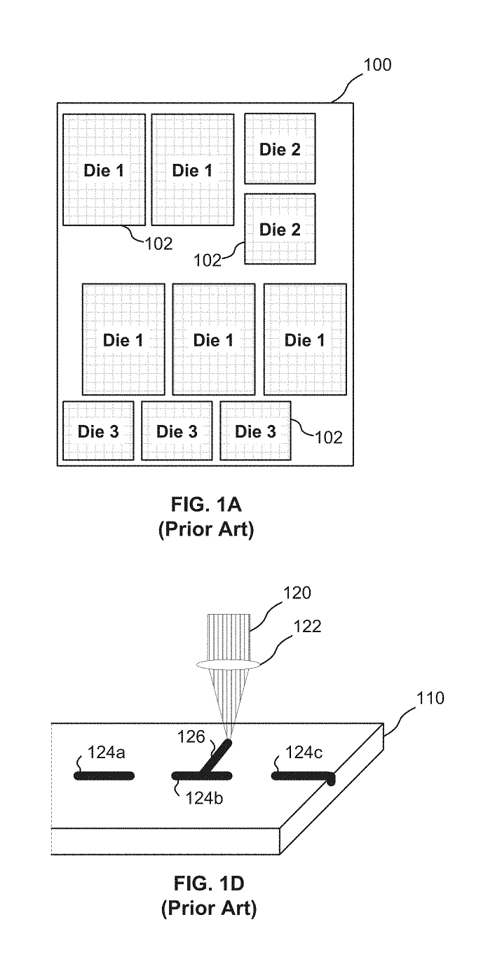

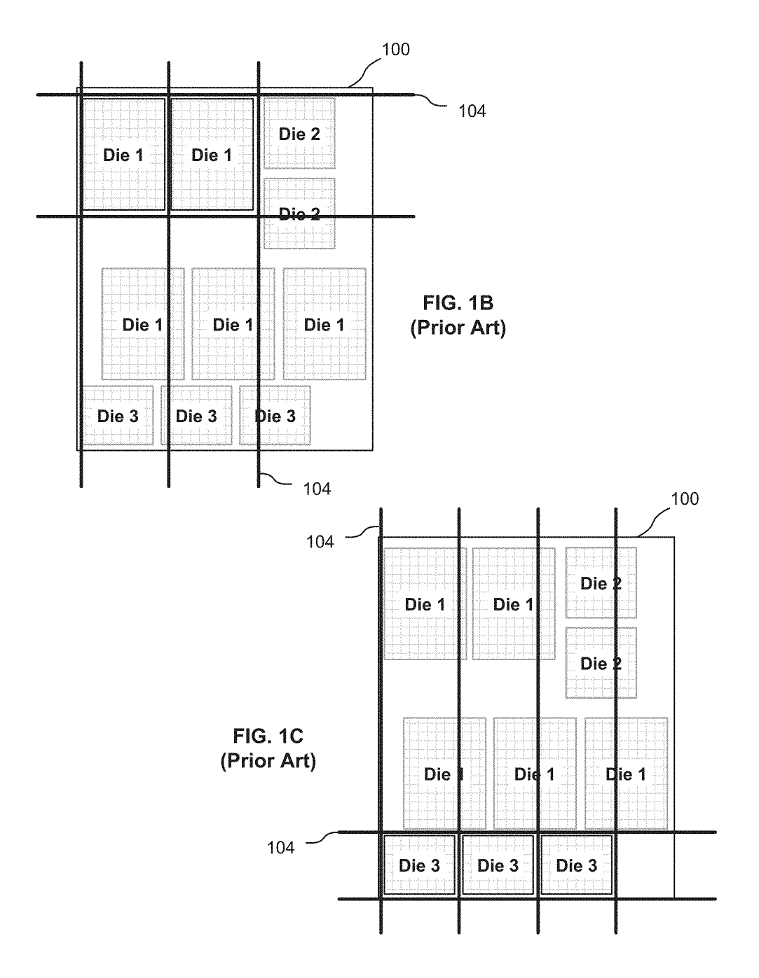

By combining front-side ablative laser scribed cuts and aligned modified layers created through the backside of a wafer substrate by an IR stealth dicing laser, approximately 90-100% wafer substrate utilization can be achieved, even with MPWs. Using the example of FIGS. 1A-1C above, instead of dicing four wafer substrates to obtain samples of all types of IC dies, only one wafer substrate need be diced with the inventive method described above. Further, since the kerf generated by the ablative laser is very small (essentially only limited by the focus spot diameter of the ablative laser), and stealth dicing has essentially no kerf width, the fine cuts available with the inventive methods along with centro-symmetric expansion allow dicing of ICs as small as 0.4 mm of a die side size. The result is significant cost savings due to (1) increased yield (fewer wafer substrates are required to produce a desired number of usable IC dies, more IC dies can be patterned per wafer substrate due to decreased cutting street widths, and IC die cutting defects are reduced) and (2) reduced process cycle time (fewer wafer substrates are required to be processed to produce a desired number of usable IC dies, and less engineering setup and processing time is required to generate cutting plans for multiple wafer substrates).

### Alternatives

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, or parallel fashion. It is to be understood that the foregoing description is intended to illustrate and not to limit the scope of the invention, which is defined by the scope of the following claims, and that other embodiments are within the scope of the claims. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A method of dicing a wafer substrate patterned on its front side with integrated circuit (IC) dies in a non-uniform grid pattern and having its backside adhered to a dicing tape, including the steps of:
(a) mapping target IC dies on the patterned front-side of the wafer substrate to determine the locations of cutting streets defining the non-uniform grid pattern of IC dies;
(b) from the front side of the wafer substrate, using an ablative laser to make scribing passes around target IC dies inside the mapped cutting streets, wherein the ablative laser is intermittently stopped and started to make scribed cuts only inside the mapped cutting streets defining the non-uniform grid pattern of IC dies;
(c) mapping target IC dies on the patterned front-side of the wafer substrate to determine the locations of the front-side ablative laser scribed cuts;
(d) from the backside of the wafer substrate, using a penetrating laser to make stealth dicing passes through the dicing tape and around target IC dies substantially aligned with the mapped front-side ablative laser scribed cuts, wherein the penetrating laser is intermittently stopped and started to make the stealth dicing passes only when substantially aligned with the mapped front-side ablative laser scribed cuts; and
(e) expanding the wafer substrate with all laser processed IC dies, thereby singulating the IC dies from the wafer substrate.

2. The method of claim 1, wherein mapping target IC dies on the patterned front-side of the wafer substrate to determine the locations of the front-side ablative laser scribed cuts is performed from the backside of the wafer substrate.

3. The method of claim 1, wherein mapping target IC dies on the patterned front-side of the wafer substrate to determine the locations of the front-side ablative laser scribed cuts is performed from the front side of the wafer substrate.

4. The method of claim 1, wherein at least two dies in the non-uniform grid pattern are of different sizes.

5. The method of claim 1, wherein expanding includes centro-symmetric expansion.

6. The method of claim 1, wherein using a penetrating laser to make the stealth dicing passes includes making subsurface sites within the wafer substrate suitable to form preferred cleaving planes.

7.-19. (canceled)
